(19) United States
(12) Patent Application Publication
(10) Pub. No.: US 2016/0111412 A1
(43) Pub. Date: Apr. 21, 2016

(54) ESD PROTECTION CIRCUIT

(71) Applicant: SOLUM CO., LTD., Suwon-si (KR)

(72) Inventor: Jae Hyun LEE, Suwon-si (KR)

(73) Assignee: SOLUM CO., LTD., Suwon-si (KR)

(21) Appl. No.: 14/663,081

(22) Filed: Mar. 19, 2015

(30) Foreign Application Priority Data
Oct. 21, 2014 (KR) 10-2014-0142613

(51) Int. Cl. H01L 27/02; H01L 27/06

(52) U.S. Cl. CPC H01L 27/0248; H01L 27/0629

(57) ABSTRACT

An electrostatic discharge (ESD) protection circuit may include an n-channel metal oxide semiconductor (NMOS) having a drain connected to a power terminal and a source and a gate connected to a ground terminal, a capacitor connected to the drain and a bulk terminal of the NMOS in parallel, and a plurality of series-connected diodes having anodes of one ends thereof connected to the bulk terminal and cathodes of the other ends thereof connected to the ground terminal.

### CROSS-REFERENCE TO RELATED APPLICATION

This application claims priority to, and the benefit of, Korean Patent Application No. 10-2014-0142613 filed on Oct. 21, 2014, with the Korean Intellectual Property Office, the disclosure of which is incorporated herein by reference.

### BACKGROUND

The present disclosure relates to an electrostatic discharge (ESD) protection circuit.

An electrostatic discharge (ESD), a phenomenon in high voltage electrostatic charge is instantaneously discharged (an electrostatic discharge), destroys semiconductor devices and metal wirings in an integrated circuit (IC) and causes malfunctioning of the circuit.

Therefore, a typical semiconductor apparatus employs an ESD protection circuit, wherein a device used for designing the ESD protection circuit is referred to as an ESD protection device.

Examples of ESD protection devices generally include a non-snapback type diode, a snapback type gate grounded n-channel metal oxide semiconductor (NMOS), agate coupled NMOS, and the like.

Meanwhile, a gate grounded NMOS having a structure in which a gate and a source are connected to each other in an existing NMOS structure, may be manufactured by an existing complementary metal-oxide semiconductor (CMOS) process without adding a new process and has been widely used as the ESD protection device of the IC based on an MOSFET.

### RELATED ART DOCUMENT

(Patent Document 1) Korean Patent Application No. 10-2007-0016256

### SUMMARY

An aspect of the present disclosure may provide an electrostatic discharge (ESD) protection circuit having a low triggering voltage and a high holding current.

According to an aspect of the present disclosure, an electrostatic discharge (ESD) protection circuit may include an n-channel metal oxide semiconductor (NMOS) having a drain connected to a power terminal and a source and a gate connected to a ground terminal, a capacitor connected to the drain and a bulk terminal of the NMOS in parallel, and a plurality of series-connected diodes having anodes of one ends thereof connected to the bulk terminal and cathodes of the other ends thereof connected to the ground terminal.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a cross-sectional view illustrating a configuration of an electrostatic discharge (ESD) protection circuit according to an exemplary embodiment in the present disclosure;

FIG. 2 is an equivalent circuit diagram of the ESD protection circuit according to an exemplary embodiment in the present disclosure;

FIG. 3 is an equivalent circuit diagram of the ESD protection circuit at the time of a normal operation of the ESD protection circuit, according to an exemplary embodiment in the present disclosure;

FIG. 4A is a cross-sectional view illustrating a discharge path at the time of a first operation of the ESD protection circuit, according to an exemplary embodiment in the present disclosure;

FIG. 4B is an equivalent circuit diagram illustrating the discharge path at the time of the first operation of the ESD protection circuit, according to an exemplary embodiment in the present disclosure;

FIG. 5A is a cross-sectional view illustrating a discharge path at the time of a second operation of the ESD protection circuit, according to an exemplary embodiment in the present disclosure;

FIG. 5B is an equivalent circuit diagram illustrating the discharge path at the time of the second operation of the ESD protection circuit, according to an exemplary embodiment in the present disclosure; and

FIG. 6 is an operation characteristic view of the ESD protection circuit according to an exemplary embodiment in the present disclosure.

### DETAILED DESCRIPTION

Exemplary embodiments in the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

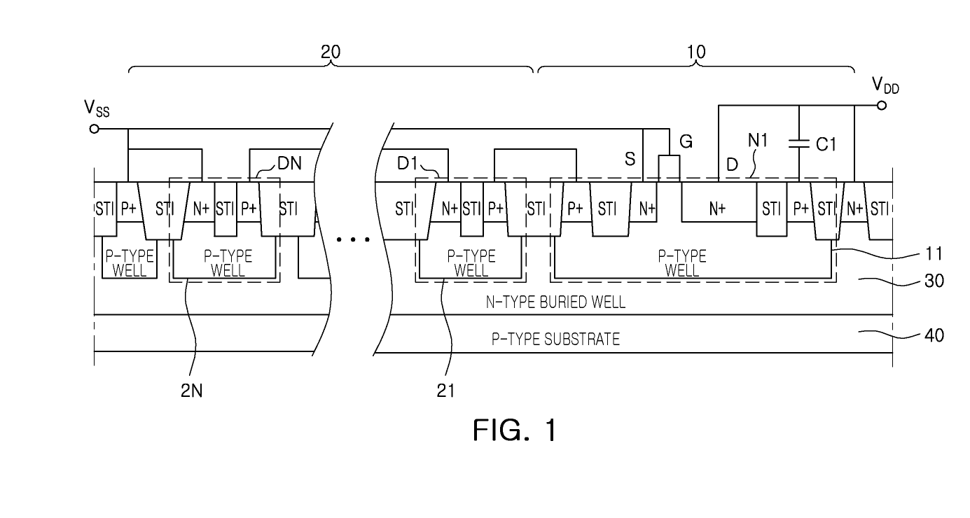

FIG. 1 is a cross-sectional view illustrating a configuration of an electrostatic discharge (ESD) protection circuit according to an exemplary embodiment in the present disclosure.

Referring to FIG. 1, the ESD protection circuit according to the present disclosure may include a n-channel metal oxide semiconductor (NMOS) included in a NMOS region 10, a capacitor C1, and a plurality of series-connected diodes D1 to DN included in a diode region 20.

The NMOS and the plurality of series-connected diodes D1 to DN may be formed on one substrate and may be formed by a standard CMOS process.

A drain D of the NMOS may be connected to a power terminal V_{DD}, and a source S and a gate G thereof may be connected to a ground terminal V_{SS}.

The capacitor C1 may be connected between the drain D and a bulk terminal of the NMOS, an anode of the first diode D1 among the plurality of series-connected diodes D1 to DN may be connected to the bulk terminal, and a cathode of the N-th diode DN may be connected to the ground terminal Vₛₛ.

The drain D and the source S may be formed in an n-type terminal included in a first p-type well 11.

The plurality of series-connected diodes D1 to DN may be each formed in a plurality of second p-type wells 21 to 2N which are spaced apart from the first p-type well 11.

The first p-type well 11 and the plurality of second p-type wells 21 to 2N may be formed in an n-type buried well 30 in a state in which they are separated from each other.

A separator that separates the n-type terminal included in the first p-type well 11 and the second p-type wells 21 to 2N from a p-type terminal and separates the first p-type well and the plurality of second p-type well 21 to 2N from each other in the n-type buried well 30 may be a shallow trench isolation obtained by forming a shallow trench and then filling the trench with an insulating material.

Meanwhile, the plurality of series-connected diodes may be p-n junction diode respectively formed in the plurality of second p-type wells 21 to 2N.

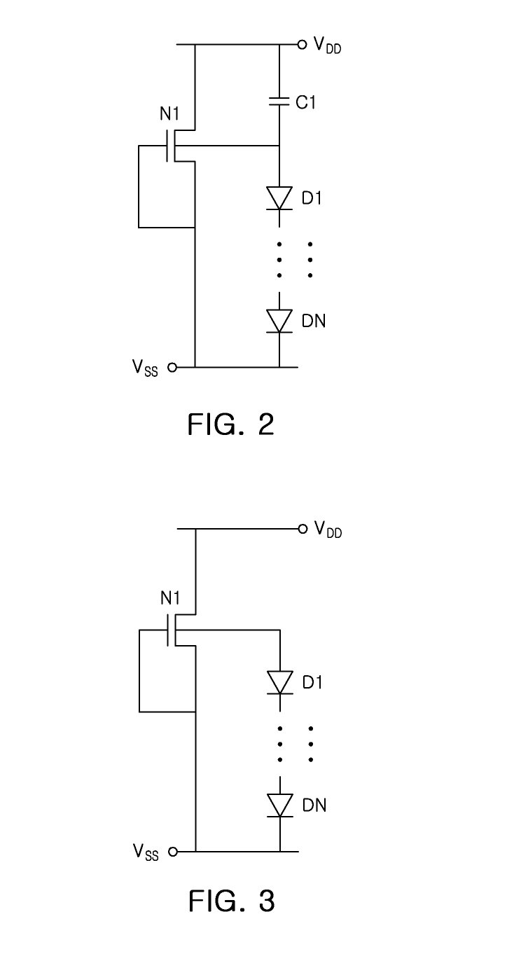

FIG. 2 is an equivalent circuit diagram of the ESD protection circuit according to an exemplary embodiment in the present disclosure.

Referring to FIG. 2, the drain D of the NMOS N1 may be connected to the power terminal V_{DD}, and the source S and the gate G thereof may be connected to the ground terminal V_{SS}.

The capacitor C1 may be connected between the drain D and the bulk terminal of the NMOS N1, anodes of one ends thereof of the plurality of series-connected diodes D1 to DN may be connected to the bulk terminal, and cathodes of the other ends thereof may be connected to the ground terminal V_{SS}.

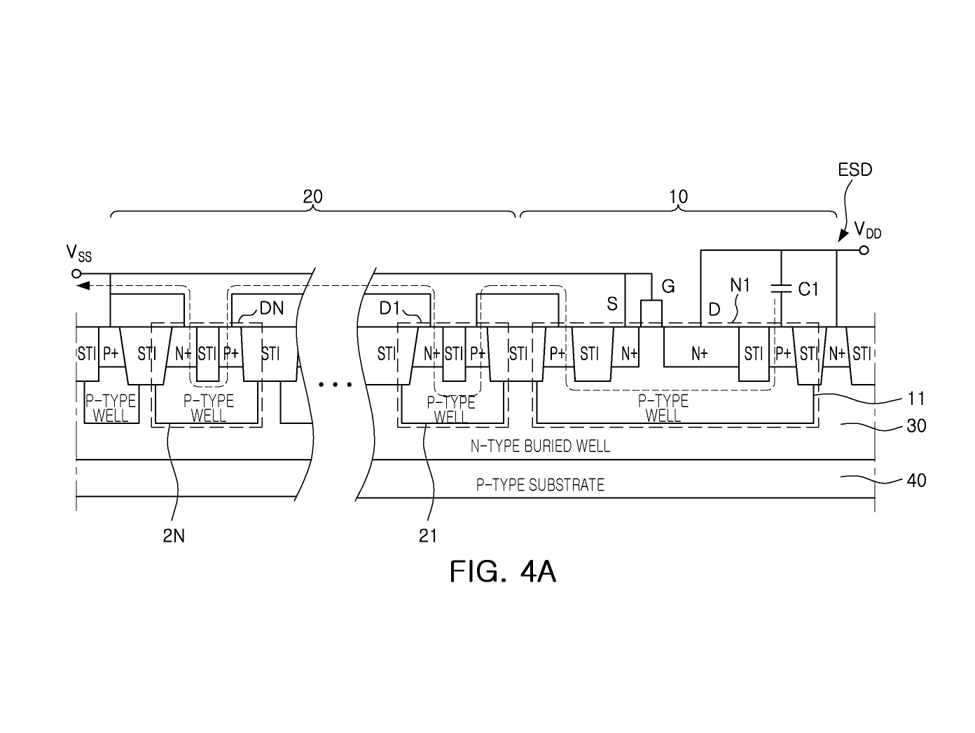

FIG. 3 is an equivalent circuit diagram of the ESD protection circuit at the time of a normal operation, according to an exemplary embodiment in the present disclosure.

Referring to FIGS. 2 and 3, when the power terminal V_{DD} is at a constant voltage state and a normal operation that does not occur an electrostatic discharge is performed, the capacitor C1 (FIG. 2) may be maintained in an open state and the NMOS may be maintained in a non-operation state.

Therefore, when the normal operation that does not cause the electrostatic discharge is performed, a current may not flow in the protection circuit.

In the case in which the electrostatic discharge occurs, the ESD protection circuit may be operated in a first operation and a second operation. Hereinafter, the first operation and the second operation will be described with reference to the drawings.

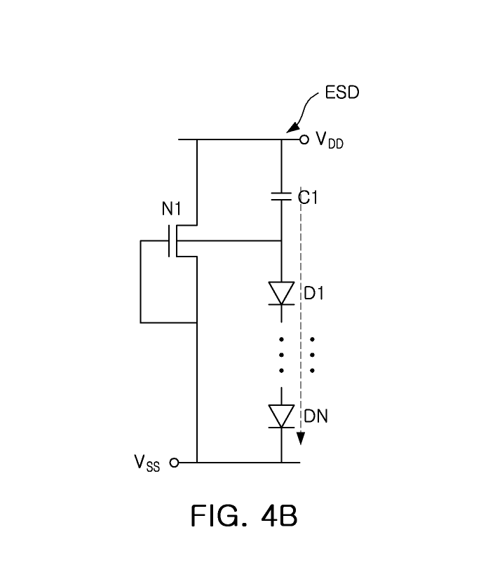

FIG. 4A is a cross-sectional view illustrating a discharge path at the time of the first operation, according to an exemplary embodiment in the present disclosure.

FIG. 4B is an equivalent circuit diagram illustrating the discharge path at the time of the first operation of the ESD protection circuit, according to an exemplary embodiment in the present disclosure.

Referring to FIGS. 4A and 4B, the ESD protection circuit according to the present disclosure may include the n-channel metal oxide semiconductor (NMOS) included in the NMOS region 10, the capacitor C1, and the plurality of diodes D1 to DN included in the diode region 20.

The drain D of the NMOS may be connected to the power terminal V_{DD}, and the source S and the gate G thereof may be connected to the ground terminal V_{SS}.

The capacitor C1 may be connected between the drain D and the bulk terminal of the NMOS, and the plurality of diodes D1 to DN may be connected to each other in series between the bulk terminal and the ground terminal and shunt the current after an application of the electrostatic discharge and before an operation of the NMOS N1.

That is, at the time of the first operation in which the NMOS N1 is not operated after the electrostatic discharge occurs, an electrostatic discharge current that is not the constant voltage but a noise form may flow into the capacitor, and the electrostatic discharge current may be discharged to the ground terminal V_{SS} through the plurality of diodes D1 to DN.

Meanwhile, during the first operation, a high voltage may be applied to the drain D formed in the first p-type well 11 by the electrostatic discharge applied to the power terminal V_{DD}, and a potential of the bulk terminal may be increased by forward voltages of the plurality of series-connected diodes.

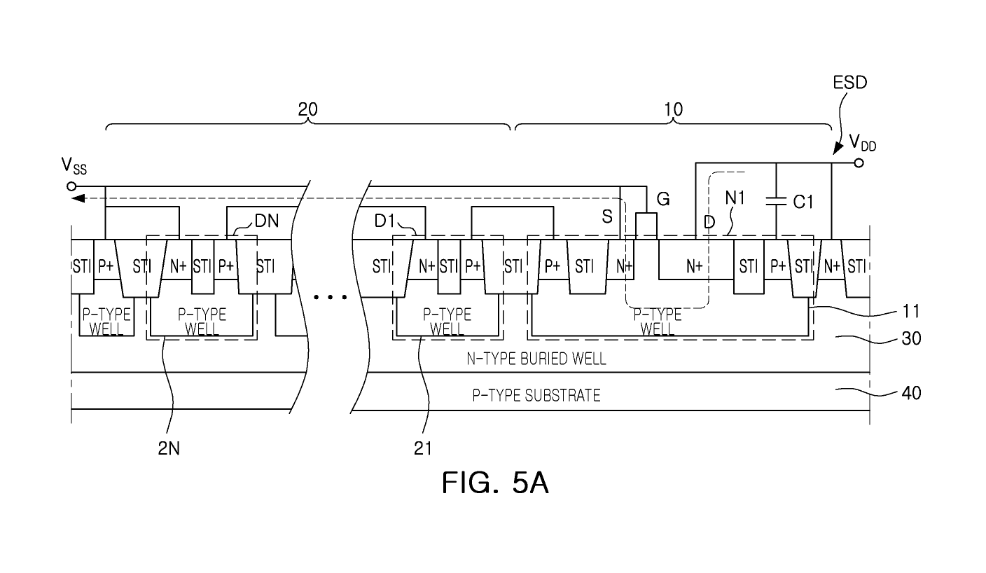

FIG. 5A is a cross-sectional view illustrating a discharge path at the time of the second operation of the ESD protection circuit, according to an exemplary embodiment in the present disclosure.

FIG. 5B is an equivalent circuit diagram illustrating the discharge path at the time of the second operation of the ESD protection circuit, according to an exemplary embodiment in the present disclosure.

Referring to FIGS. 5A and 5B, at the time of the second operation in which the NMOS N1 is turned on after the electrostatic discharge occurs, the electrostatic discharge current flowing into the plurality of diodes D1 to DN may change a flow path thereof, so as to be discharged to the ground terminal V_{SS} connected to the source S of the NMOS N1 through NMOS N1.

Specifically, during the first operation, a high voltage may be applied to the drain D formed in the first p-type well 11 by the electrostatic discharge applied to the power terminal V_{DD}, and a potential of the bulk terminal may be increased by forward voltages of the plurality of series-connected diodes D1 to DN.

In the case in which the potential of the bulk terminal is sufficiently increased by the forward voltages of the plurality of series-connected diodes D1 to DN, a parasitic bipolar transistor included in the first p-type well 11 may be operated.

Therefore, the NMOS N1 is turned on, such that the electrostatic discharge current applied to the drain D of the NMOS N1 may be discharged to the ground terminal V_{SS} connected to the source S of the NMOS N1 through the NMOS N1.

Meanwhile, an active voltage for the turn-on operation of the parasitic bipolar transistor may be determined by threshold voltages of the plurality of series-connected diodes.

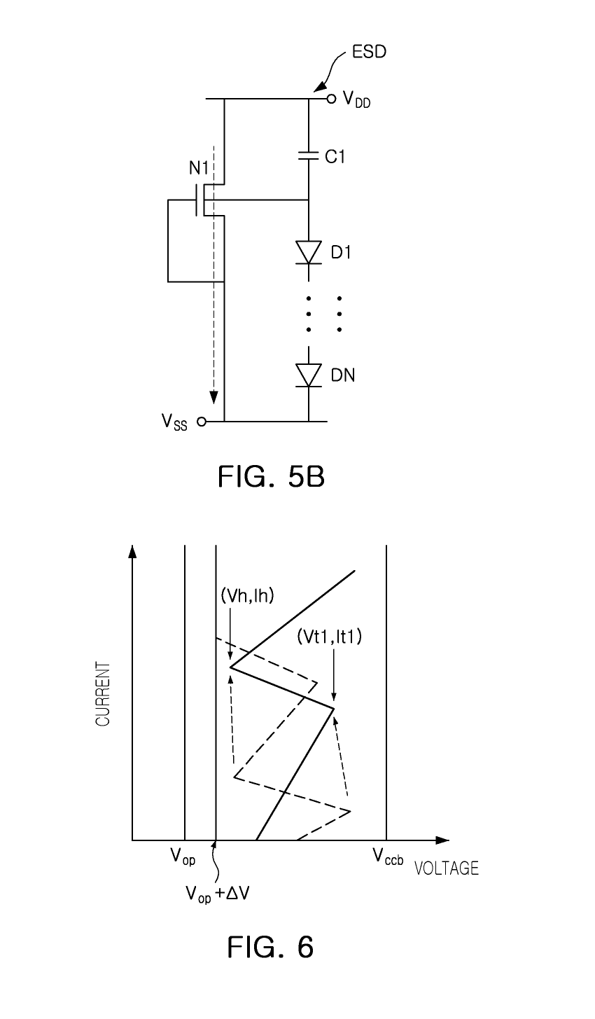

FIG. 6 is an operation characteristic view of the ESD protection circuit according to an exemplary embodiment in the present disclosure.

Referring to FIG. 6, a characteristic graph of an NMOS protection circuit according to the related art illustrated by a dotted line and an operation characteristic graph of the ESD protection circuit according an exemplary embodiment in the present disclosure illustrated by a solid line may be seen.

A triggering voltage Vt1 of the NMOS included in the ESD protection circuit according to an exemplary embodiment in the present disclosure may have a voltage level higher than a summation of an operation voltage Vₒₚ and a voltage margin ΔV by taking account of the voltage margin ΔV, in order that the current does not flow through the ESD protection circuit when a voltage of the operation voltage Vₒₚ or less is applied to the ESD protection circuit in a state in which a semiconductor apparatus adopting the ESD protection circuit is normally operated.

In addition, in the case in which the electrostatic discharge occurs in the semiconductor apparatus, the triggering voltage Vt1 may have a voltage level lower than a breakdown voltage Vccb of an internal circuit so as to sufficiently protect the internal circuit.

The triggering voltage Vt1 may be determined by the threshold voltages of the plurality of series-connected diodes.

Meanwhile, a holding current Ih according to an exemplary embodiment in the present disclosure may have a high current value of the operation current or more in order to prevent a latch up that causes thermal breakdown by an excessive current flowing through the ESD protection circuit due to a snapback phenomenon.

That is, the electrostatic discharge (ESD) protection circuit according to an exemplary embodiment in the present disclosure may have a low triggering voltage Vt1 and a high holding current Ih.

As set forth above, according to exemplary embodiments in the present disclosure, the electrostatic discharge (ESD) protection circuit may have the low triggering voltage and the high holding current.

While exemplary embodiments have been shown and described above, it will be apparent to those skilled in the art that modifications and variations could be made without departing from the scope in the present invention as defined by the appended claims.

What is claimed is:

1. An electrostatic discharge (ESD) protection circuit comprising:
an n-channel metal oxide semiconductor (NMOS) having a drain connected to a power terminal and a source and a gate connected to a ground terminal;
a capacitor connected between the drain and a bulk terminal of the NMOS; and
a plurality of series-connected diodes having anodes of one ends thereof connected to the bulk terminal and cathodes of the other ends thereof connected to the ground terminal.

2. The ESD protection circuit of claim 1, wherein the drain and the source are formed in an n-type terminal included in a first p-type well.

3. The ESD protection circuit of claim 1, wherein a parasitic bipolar transistor included in the first p-type well is operated by an electrostatic discharge applied to the power terminal.

4. The ESD protection circuit of claim 1, wherein the NMOS has a triggering voltage determined by threshold voltages of the plurality of series-connected diodes.

5. The ESD protection circuit of claim 2, wherein the plurality of series-connected diodes are respectively formed in a plurality of second p-type wells which are spaced apart from the first p-type well.

6. The ESD protection circuit of claim 5, wherein the first p-type well and the plurality of second p-type wells are formed in an n-type buried well in a state in which the first p-type well and the plurality of second p-type wells are separated from each other.

7. The ESD protection circuit of claim 1, wherein the plurality of series-connected diodes are p-n junction diodes.

8. An electrostatic discharge (ESD) protection circuit comprising:
an n-channel metal oxide semiconductor (NMOS) having a drain connected to a power terminal and a source and a gate connected to a ground terminal;
a capacitor connected between the drain and a bulk terminal of the NMOS; and
a plurality of diodes connected to each other in series between the bulk terminal and the ground terminal and shunting a current after an application of an electrostatic discharge and before an operation of the NMOS.

9. The ESD protection circuit of claim 8, wherein the drain and the source are formed in an n-type terminal included in a first p-type well.

10. The ESD protection circuit of claim 8, wherein a parasitic bipolar transistor included in the first p-type well is operated by an electrostatic discharge applied to the power terminal.

11. The ESD protection circuit of claim 8, wherein the NMOS has a triggering voltage determined by threshold voltages of the plurality of diodes.

12. The ESD protection circuit of claim 9, wherein the plurality of diodes are respectively formed in a plurality of second p-type wells which are spaced apart from the first p-type well.

13. The ESD protection circuit of claim 12, wherein the first p-type well and the plurality of second p-type wells are formed in an n-type buried well in a state in which the first p-type well and the plurality of second p-type wells are separated from each other.

14. The ESD protection circuit of claim 8, wherein the plurality of diodes are p-n junction diodes.

15. An electrostatic discharge (ESD) protection circuit comprising:
an n-channel metal oxide semiconductor (NMOS) having a drain connected to a power terminal, a source and a gate connected to a ground terminal, and a parasitic bipolar capacitor;
capacitors connected to the drain and a bulk terminal of the NMOS in parallel; and
a plurality of series-connected diodes having anodes of one ends thereof connected to the bulk terminal and cathodes of the other ends thereof connected to the ground terminal to shunt a current after an application of an electrostatic discharge and before an operation of the NMOS.

16. The ESD protection circuit of claim 15, wherein the drain and the source are formed in an n-type terminal included in a first p-type well.

17. The ESD protection circuit of claim 15, wherein the parasitic bipolar transistor is operated by an electrostatic discharge applied to the power terminal.

18. The ESD protection circuit of claim 15, wherein the NMOS has a triggering voltage determined by threshold voltages of the plurality of series-connected diodes.

19. The ESD protection circuit of claim 16, wherein the plurality of series-connected diodes are respectively formed in a plurality of second p-type wells which are spaced apart from the first p-type well.

20. The ESD protection circuit of claim 19, wherein the first p-type well and the plurality of second p-type wells are formed in an n-type buried well in a state in which the first p-type well and the plurality of second p-type wells are separated from each other.

21. The ESD protection circuit of claim 15, wherein the plurality of series-connected diodes are p-n junction diodes.
